(19) United States
(12) Patent Application Publication
(10) Pub. No.: US 2017/0212425 A1
(43) Pub. Date: Jul. 27, 2017

(54) EXPOSURE APPARATUS

(71) Applicant: DISCO CORPORATION, Tokyo (JP)

(72) Inventor: Kazuma Sekiya, Tokyo (JP)

(21) Appl. No.: 15/416,600

(22) Filed: Jan. 26, 2017

(30) Foreign Application Priority Data
Jan. 27, 2016 (JP) 2016-013259

(51) Int. Cl. G03F 7/20

(52) U.S. Cl. CPC G03F 7/70058

(57) ABSTRACT

An exposure apparatus includes a light source, an illumination optical system, a mask, and a projection optical system. The mask is configured from a plurality of small masks individually formed from small patterns in a plurality of regions into which a pattern to configure one device is divided. The projection optical system is configured in a size corresponding to a size of the small masks and projecting the small patterns in a reduced scale on a substrate. The necessity for a projection optical system for which accuracy against aberration is demanded and a high-price lens is used is eliminated, and it is possible to use a projection optical system configured from a small-sized lens having a small projection area and less liable to be influenced by aberration. Consequently, the exposure apparatus can be provided at a reduced cost.

### BACKGROUND OF THE INVENTION

Field of the Invention

The present invention relates to an exposure apparatus for use with projection of a circuit pattern in a reduced scale.

Description of the Related Art

A wafer having a plurality of devices such as integrated circuits (ICs) or large-scale integrations (LSIs) formed on the surface thereof and partitioned by scheduled division lines is divided into individual device chips by a dicing apparatus or the like. The device chips are utilized for various kinds of electronic apparatus such as a portable telephone set or a personal computer.

Devices on a wafer are configured as three-dimensional circuits by coating a resist film on an upper face of a semiconductor substrate such as a silicon substrate, projecting circuit patterns in a reduced scale by an exposer apparatus called stepper and repeating etching and projection by a plural number of times.

The exposure apparatus includes a light source that emits an ultraviolet laser beam, a mask called reticle configured in a unit of a pattern including a group of a plurality of devices, and a projection lens. The exposure apparatus projects, while a substrate of a target of projection and the projection lens are relatively moved, a desired reduced pattern on an upper face of the semiconductor substrate (for example, refer to Japanese Patent Laid-Open No. 1992-225357).

### SUMMARY OF THE INVENTION

However, the exposure apparatus has a problem in that a high cost is required because the projection lens is configured such that an aberration does not appear in a range from the center at which a pattern is projected to an outer periphery.

Therefore, it is an object of the present invention to provide an exposure apparatus that is simple in configuration and less expensive.

In accordance with an aspect of the present invention, there is provided an exposure apparatus including a light source, an illumination optical system, a mask, and a projection optical system, the mask being configured from a plurality of small masks individually formed from small patterns in which a pattern configuring one device is divided in a plurality of regions, the projection optical system being configured in a size corresponding to a size of the small masks and projecting the small patterns in a reduced scale on a substrate.

Preferably, the small masks are disposed on mask selection means to be selectively positioned with respect to the projection optical system, and the small patterns are projected in a reduced scale to a given position of a region configuring one device. The small patterns may be projected in a reduced scale such that part of the small patterns overlaps with each other and wiring patterns may be connected to the small patterns, or the small patterns may be projected in a reduced scale so as not to overlap with each other, and for wiring between the small patterns, wiring patterns may be projected in a reduced scale to connect the small patterns. Preferably, the substrate on which the small patterns are to be projected in a reduced scale has a size of 10 to 20 mm in diameter.

The mask in the exposure apparatus of the present invention is configured from a plurality of small masks individually formed from small patterns in a plurality of regions into which a pattern to configure one device is divided, and the projection optical system is configured in a size corresponding to a size of the small masks and projects the small patterns in a reduced scale on a substrate. Therefore, in place of a projection optical system for which accuracy against aberration is demanded cumulatively as the projection area increases and a high-price lens is used, a projection optical system configured from a small-sized lens having a small projection area and less liable to be influenced by aberration can be used. Consequently, the exposure apparatus can be provided at a reduced cost.

Further, where the exposure apparatus is configured such that the small masks are disposed on the mask selection means to be selectively positioned with respect to the projection optical system and the small patterns are projected in a reduced scale to the given position of a region in which one device is to be configure, the small patterns can be changed over efficiently to perform exposure to project patterns for fabrication of one device in a reduced scale by the single exposure apparatus.

The small patterns are projected in a reduced scale such that part of the small patterns overlaps with each other and wiring patterns are connected to the small patterns, or the small patterns are projected in a reduced scale so as not to overlap with each other and, for wiring between the small patterns, wiring patterns are projected in a reduced scale to connect the small patterns. By any of the countermeasures, adjacent ones of the small patterns can be connected with certainty.

The above and other objects, features and advantages of the present invention and the manner of realizing them will become more apparent, and the invention itself will best be understood, from a study of the following description and appended claims with reference to the attached drawings showing some preferred embodiments of the invention.

### BRIEF DESCRIPTION OF THE DRAWINGS

FIG. 1 is a perspective view depicting a case in which a mask of a first embodiment is used in an exposure apparatus;

FIGS. 2A to 2D are top plan views depicting a procedure in which patterns are successively projected using the mask of the first embodiment;

FIG. 3 is a top plan view depicting a workpiece after development;

FIG. 4 is a perspective view depicting a second embodiment of the mask;

FIGS. 5A to 5D are top plan views depicting a procedure in which patterns are successively projected using the mask of the second embodiment;

FIG. 6 is a top plan view depicting a workpiece after wiring is performed for the workpiece on which patterns are projected using the mask of the second embodiment;

FIG. 7 is a perspective view depicting a third embodiment of the mask; and

FIG. 8 is a perspective view depicting a fourth embodiment of the mask.

### DETAILED DESCRIPTION OF THE PREFERRED EMBODIMENTS

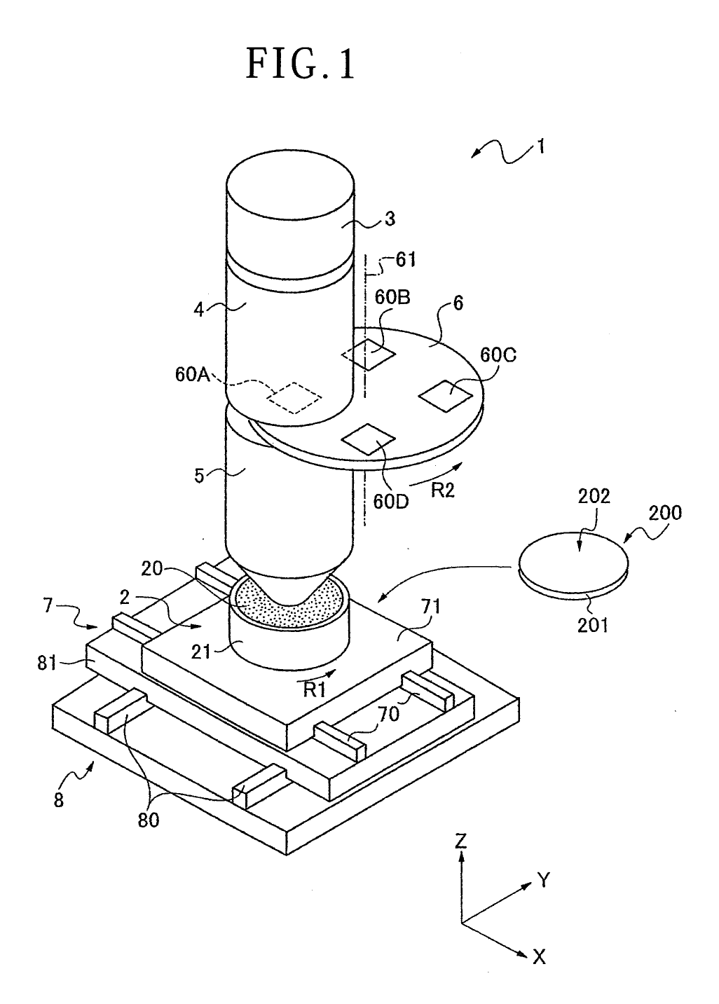

An exposure apparatus 1 depicted in FIG. 1 includes a holding table 2 for holding a workpiece of an exposure target thereon, a light source 3 that emits light such as ultraviolet rays, an illumination optical system 4 that introduces the light emitted from the light source 3 in a downwardly vertical direction (Z direction), a projection optical system 5 that projects the light introduced from the illumination optical system 4 toward a workpiece held on the holding table 2, and mask selection means 6 positioned between the illumination optical system 4 and the projection optical system 5.

The holding table 2 is configured from a suction unit 20 configured from a porous member and a frame body 21 surrounding the suction unit 20, and the suction unit 20 is communicated with a suction source not depicted. The holding table 2 is driven by a pulse motor not depicted for rotation over a predetermined angle and also is driven by an X direction driving mechanism 7 and a Y direction driving mechanism 8 for movement in the X direction and the Y direction, respectively.

The X direction driving mechanism 7 includes a pair of rails 70 extending in the X direction and a movable base 71 which contacts at a lower portion thereof for sliding movement with the rails 70 and has the holding table 2 disposed at an upper portion thereof. A linear motor or the like is provided on the movable base 71 such that the movable base 71 can be moved in the X direction under the guidance of the rails 70. As the movable base 71 moves in the X direction, also the holding table 2 moves in the X direction. It is to be noted that the X direction driving mechanism 7 may be configured otherwise such that the holding table 2 is moved in the X direction by a ball screw mechanism.

The Y direction driving mechanism 8 includes a pair of rails 80 extending in the Y direction and a movable base 81 which contacts at a lower portion thereof for sliding movement with the rails 80. A linear motor or the like is provided on the movable base 81 such that the movable base 81 is moved in the Y direction under the guidance of the rails 80. As the movable vase 81 moves in the Y direction, also the holding table 2 moves in the Y direction. It is to be noted that the Y direction driving mechanism 8 may be configured such that the holding table 2 is moved in the Y direction by a ball screw mechanism. The illumination optical system 4 includes a shutter not depicted in the inside thereof such that, when the shutter is opened, light emitted from the light source 3 passes therethrough toward the projection optical system 5.

The mask selection means 6 in the example of FIG. 1 is formed in the form of a disk and includes a mask configured from four small masks 60A, 60B, 60C and 60D. On each of the four small masks 60A, 60B, 60C and 60D, a pattern to be formed on a substrate held on the holding table 2 is formed. The patterns formed on the small masks 60A, 60B, 60C and 60D are different from each other, and, by combining all of the patterns, one device pattern is completed. In other words, the mask in the exposure apparatus 1 is formed from divisional masks 60A to 60D configured from small patterns in which a pattern configuring one device is divided in a plurality of regions.

The mask selection means 6 is rotatable around the center provided by a rotational axis 61, and is configured such that, by stepwise rotation by 90 degrees, one of the four small masks 60A, 60B, 60C and 60D is selectively positioned on an optical path of the illumination optical system 4 and the projection optical system 5.

The projection optical system 5 includes a projection lens and projects light having passed through one of the small masks positioned on the optical path of the illumination optical system 4 toward a workpiece held by the holding table 2. The projection optical system 5 is formed in a size corresponding to the small masks 60A to 60D, and also the lens provided in the projection optical system 5 is formed smaller than an ordinary lens.

A workpiece 200 is sucked to and held by the holding table 2. The workpiece 200 is formed, for example, with a diameter of 10 to 20 mm and is configured from a silicon substrate 201 and a photoresist film 202 coated on an upper face of the silicon substrate 201. The photoresist film 202 is coated by applying photoresist on an overall area of an upper face of the silicon substrate 201, for example, using a spin coater and then hardening the photoresist by heating or the like. On the holding table 2, the workpiece 200 is held in a state in which photoresist film 202 is exposed upwardly. For the photoresist film 202, any of a negative type photoresist according to which a pattern of a portion at which light is irradiated remains and a positive type photoresist according to which a portion at which light is irradiated is removed by a later development process may be used.

In the following description, four embodiments are described relating to a mask and a case is described in which exposure of the photoresist film 202 is performed using small masks.

### First Embodiment

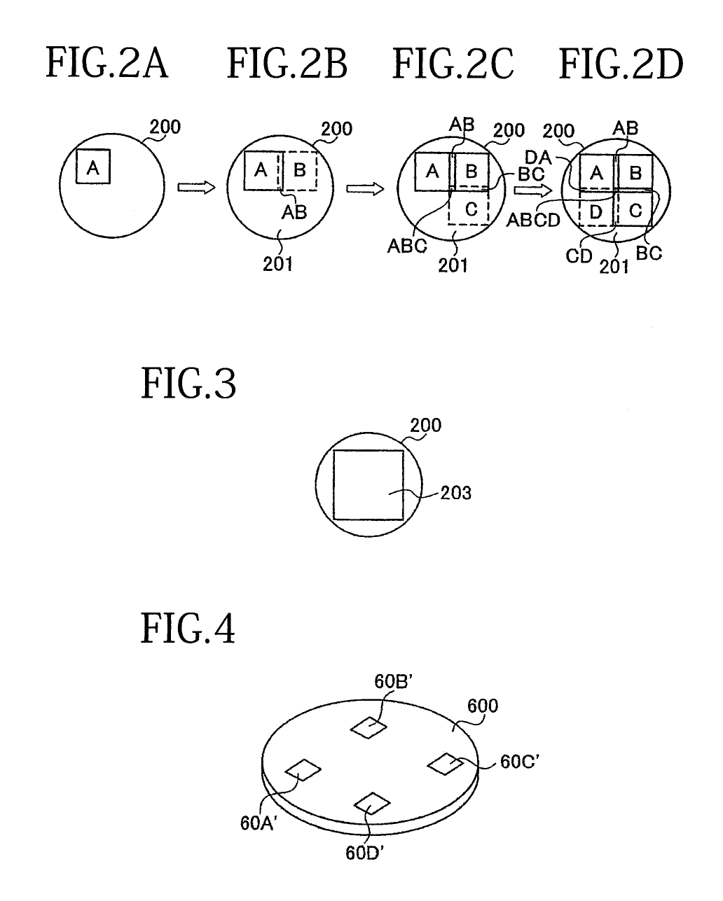

A mask configured from the small masks 60A, 60B, 60C and 60D depicted in FIG. 1 indicates a first embodiment. After the workpiece 200 is held on the holding table 2 depicted in FIG. 1, the holding table 2 is moved in an X-axis direction and a Y-axis direction until the small mask 60A of the mask selection means 6 is positioned on the optical path. Then, the shutter in the inside of the illumination optical system 4 is opened to allow light from the light source 3 to be irradiated toward the small mask 60A. The light having passed through the small mask 60A is irradiated on the photoresist film 202 through the projection optical system 5, whereupon a small pattern of the small mask 60A is projected and transferred to a given position of a region in which a device is to be configured, for example, to an exposure region A depicted in FIG. 2A from within the photoresist film 202.

Then, the holding table 2 is rotated by 90 degrees, for example, in a direction of an arrow mark R1 depicted in FIG. 1 and is moved in the X-axis direction and the Y-axis direction. Further, the mask selection means 6 is rotated by 90 degrees in a direction of an arrow mark R2 until the small mask 60B is positioned on the optical path of the illumination optical system 4 and the projection optical system 5. Then, the shutter in the inside of the illumination optical system 4 is opened to allow light from the light source 3 to be irradiated toward the small mask 60B. The light having passed through the small mask 60B is irradiated and projected on the photoresist film 202 through the projection optical system 5, whereupon a small pattern of the small mask 60B is projected and transferred, for example, to an exposure region B depicted in FIG. 2B from within the photoresist film 202.

Here, the exposure region B is formed such that part of the exposure region A and part of the exposure region B overlap with each other to form an overlapping region AB. In the overlapping region AB, the small pattern projected in the exposure region A and the small pattern projected in the exposure region B are connected to each other.

After the exposure regions A and B are formed, similarly as in the case described above, the holding table 2 is rotated by 90 degrees in the arrow mark R1 direction and is moved in the X-axis direction and the Y-axis direction. Further, the mask selection means 6 is rotated by 90 degrees in the arrow mark R2 direction until the small mask 60C is positioned on the optical path, and the shutter in the inside of the illumination optical system 4 is opened to allow the light from the light source 3 to be irradiated toward the small mask 60C. By the light having passed through the small mask 60C, as depicted in FIG. 2C, exposure of an exposure region C adjacent the exposure region B is performed, and, in the exposure region C, a small pattern of the small mask 60C is projected to the photoresist film 202.

Here, The exposure region C is formed such that part of the exposure region B and part of the exposure region C overlap with each other to form an overlapping region BC and part of the exposure region A, part of the exposure region B and part of the exposure region C overlap with each other to form an overlapping region ABC. In the overlapping region BC, a small pattern projected in the exposure region B and a small pattern projected in the exposure region C are connected to each other. In the overlapping region ABC, the small pattern projected in the exposure region A, small pattern projected in the exposure region B and small pattern projected in the exposure region C are connected to each other.

After the exposure regions A, B and C are formed, similarly as in the case described above, the holding table 2 is rotated by 90 degrees in the arrow mark R1 direction and is moved in the X-axis direction and the Y-axis direction. Further, the mask selection means 6 is rotated by 90 degrees in the arrow mark R2 direction to position a small mask 60D on the optical path, and the shutter in the inside of the illumination optical system 4 is opened to allow the light from the light source 3 to be irradiated toward the small mask 60D. By the light having passed through the small mask 60D, as depicted in FIG. 2D, exposure of the exposure region D adjacent the exposure region C is performed and, in the exposure region D, the small pattern of the small mask 60D is projected on the photoresist film 202.

Here, the exposure region D is formed such that part of the exposure region C and part of the exposure region D overlap with each other to form an overlapping region CD; part of the exposure region D and part of the exposure region A overlap with each other to form an overlapping region DA; and part of the exposure region A, part of the exposure region B, part of the exposure region C and part of the exposure region D overlap with each other to form an overlapping region ABCD. In the overlapping region CD, a pattern projected in the exposure region C and a pattern projected in the exposure region D are connected to each other. In the overlapping region DA, the pattern projected in the exposure region D and the pattern projected in the exposure region A are connected to each other. In the overlapping region ABCD, the pattern projected in the exposure region A, pattern projected in the exposure region B, pattern projected in the exposure region C and pattern projected in the exposure region D are connected to each other.

In this manner, the small patterns 60A to 60D are configured such that the projected patterns are connected to each other by forming the overlapping regions AB, BC, CD, DA and ABCD, and a pattern corresponding to a circuit pattern of one device is completed. Further, by providing the overlapping regions, the small patterns adjacent each other can be connected to each other with certainty.

Thereafter, if a degenerated portion from within the photoresist film 202 is removed by dropping developer on the photoresist film 202 and rotating the workpiece 200, then a device formation portion 203 depicted in FIG. 3 which is to make a device later is formed by performing etching along the pattern.

### Second Embodiment

On mask selection means 600 depicted in FIG. 4, small masks 60A′, 60B′, 60C′ and 60D′ are formed, and such small masks 60A′ to 60D′ are formed smaller than the small masks 60A to 60D of the mask selection means 6 depicted in FIG. 1. Similarly to the mask selection means 6 depicted in FIG. 1, the mask selection means 600 is positioned between the illumination optical system 4 and the projection optical system 5 and is provided for rotation. Further, the mask selection means 600 is configured such that, by successive rotation by 90 degrees, one of the four small masks 60A′, 60B′, 60C′ and 60D′ is positioned on the optical path of the illumination optical system 4 and the projection optical system 5.

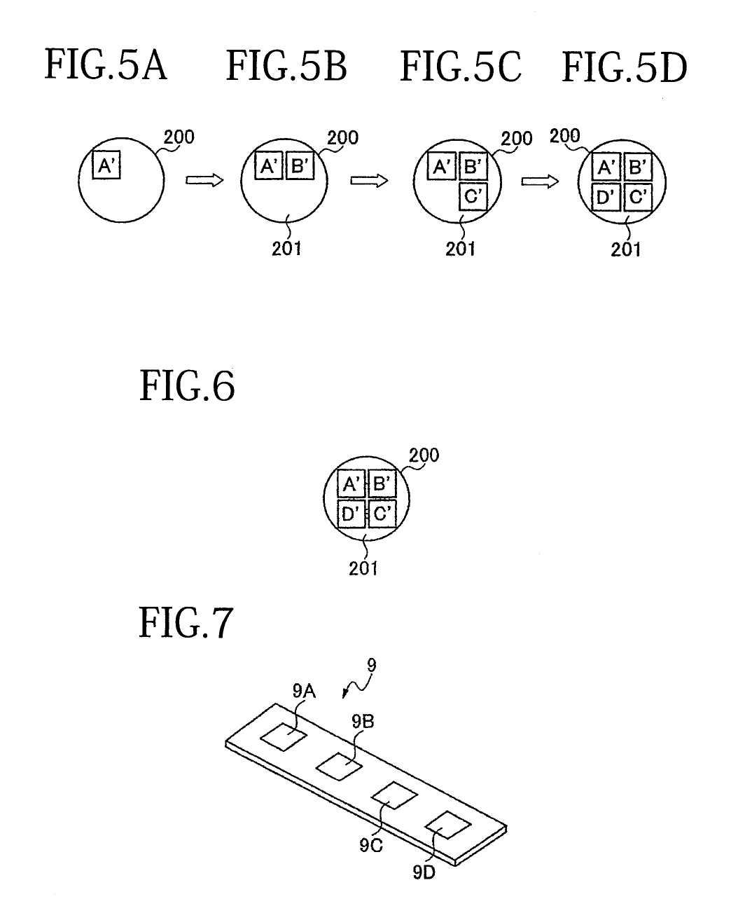

If a workpiece 200 is held on the holding table 2, then the holding table 2 is moved in the X-axis direction and the Y-axis direction until the small mask 60A′ of the mask selection means 600 is positioned on the optical path. Then, the shutter in the inside of the illumination optical system 4 is opened to allow the light from the light source 3 to be irradiated therethrough toward the small mask 60A′. The light having passed through the small mask 60A′ is irradiated on the photoresist film 202 through the projection optical system 5. As depicted in FIG. 5A, exposure of an exposure region A′ from within the photoresist film 202 is performed and, in the exposure region A′, a small pattern of the small mask 60A′ is projected on the photoresist film 202.

Thereafter, similarly as in the first embodiment, exposure is successively performed using the small masks 60B′, 60C′ and 60D′ while the holding table 2 and the mask selection means 600 are successively rotated by 90 degree. Consequently, as depicted in FIGS. 5B, 5C and 5D, exposure regions B′, C′ and D′ are formed successively and a small pattern is projected on each region.

Since the small masks 60A′ to 60D′ are formed smaller than the small masks 60A to 60D depicted in FIG. 1 and such an overlapping region as depicted in FIGS. 2A to 2D does not appear, the patterns projected on the exposure regions are not connected to each other. Therefore, a required pattern is formed in regions between the exposure region A′ and the exposure region B′, between the exposure region B′ and the exposure region C′, between the exposure region C′ and the exposure region D′, between the exposure region D′ and the exposure region A′, between the exposure region A′ and the exposure region C′ and between the exposure region B′ and the exposure region D′. As a formation method of the patterns, a method of projecting and connecting wiring patterns to be formed in the regions between the regions by exposure, another method of irradiating laser light to form wiring lines and so forth are available. If the patterns projected in the exposure regions A′ to D′ are connected to each other as depicted in FIG. 6 in this manner, then the small patterns adjacent each other are connected to each other with certainty and a pattern corresponding to a circuit pattern of one device is formed.

Thereafter, if a degenerated portion from within the photoresist film 202 is removed by dropping developer on the photoresist film 202 and rotating the workpiece 200, then a device formation portion 203 depicted in FIG. 3 which is to make a device later is formed.

### Third Embodiment

Mask selection means 9 depicted in FIG. 7 can be used in place of the mask selection means 6 in the exposure apparatus 1 depicted in FIG. 1, and includes a mask in which small masks 9A, 9B, 9C and 9D are disposed linearly. The mask selection means 9 performs exposure while the holding table 2 is rotated and fed, for example, in the X direction depicted in FIG. 1. The small masks 9A to 9D may have overlapping portions as in the first embodiment, or the small masks 9A to 9D may not have an overlapping portion similarly as in the second embodiment and may be connected to each other later by irradiation of laser light or the like.

### Fourth Embodiment

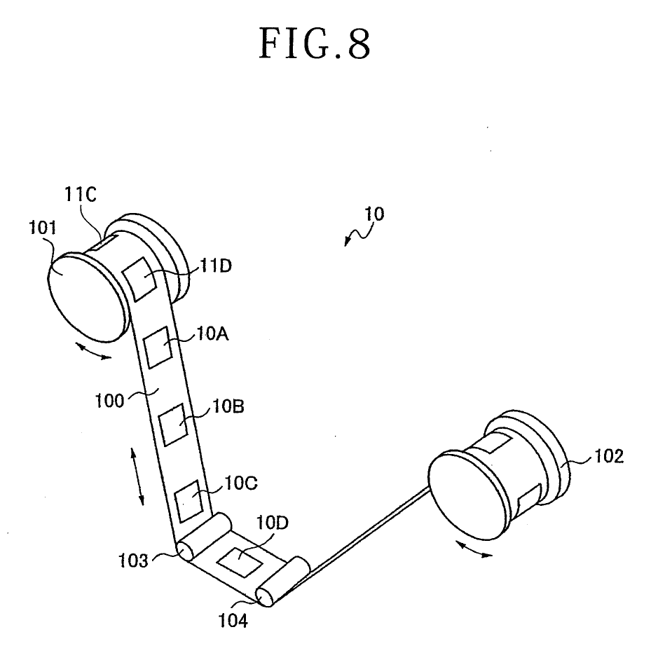

Mask selection means 10 depicted in FIG. 8 can be used in the exposure apparatus 1 depicted in FIG. 1 in place of the mask selection means 6, and includes a sheet 100 wound on a feed roller 101 and a take-up roller 102, two rollers 103 and 104 that apply tension to the sheet 100, and a mask configured from small masks 10A, 10B, 10C and 10D formed in an aligned relationship in a longitudinal direction of the sheet 100. Also different small masks individually having a small pattern different from that of each of the small masks 10A to 10D are provided (only small masks 11C and 11D are depicted in FIG. 8). The mask selection means 10 is ready for such a multilayer wiring that, for example, each of the small masks 10A to 10D has a small pattern corresponding to a first layer of a device and the different small masks have small patterns corresponding to second, third and . . . th layers of the device.

The mask selection means 10 delivers the sheet 100 using the feed roller 101 and takes up the sheet 100 using the take-up roller 102. Then, the sheet 100 is extended in a plane using the rollers 103 and 104, and one of the small masks is positioned at the projection optical system 5 to perform exposure. Each of the small masks 10A to 10D may have an overlapping portion similarly as in the first embodiment, or may not have an overlapping portion similarly as in the second embodiment and be connected to each other later by irradiation of laser light or the like.

As described above, the mask provided in the exposure apparatus according to the present invention is configured from a plurality of small masks individually formed from small patterns in a plurality of regions into which a pattern to configure one device is divided. The projection optical system 5 is configured in a size corresponding to a size of the small masks and projecting the small patterns in a reduced scale on the substrate. Therefore, a projection optical system for which accuracy against aberration is demanded cumulatively as the projection area increases and a high-price lens is used is not required, but a projection optical system configured from a small-sized lens having a small projection area and less liable to be influenced by aberration can be used. Therefore, the exposure apparatus can be provided at a low cost.

Further, the small masks are disposed on the mask selection means selectively positioned with respect to the projection optical system and the small patterns are projected to a given position of a region configuring one device. Consequently, the single exposure apparatus can perform exposure with the small patterns changed over efficiently to project the patterns for fabricating one device in a reduced scale.

It is to be noted that, while each of the masks of the embodiments is configured from four rectangular small masks, the number and the shape of the small masks to configure a mask are not limited to those of the examples indicated in the embodiments.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. An exposure apparatus, comprising:
a light source;
an illumination optical system;
a mask; and
a projection optical system,
the mask being configured from a plurality of small masks individually formed from small patterns in which a pattern configuring one device is divided in a plurality of regions;
the projection optical system being configured in a size corresponding to a size of the small masks and projecting the small patterns in a reduced scale on a substrate.

2. The exposure apparatus according to claim 1, wherein the small masks are disposed on mask selection means to be selectively positioned with respect to the projection optical system, and the small patterns are projected in a reduced scale to a given position of a region configuring one device.

3. The exposure apparatus according to claim 2, wherein the small patterns are projected in a reduced scale such that part of the small patterns overlaps with each other and wiring patterns are connected to the small patterns.

4. The exposure apparatus according to claim 2, wherein the small patterns are projected in a reduced scale so as not to overlap with each other, and for wiring between the small patterns, wiring patterns are projected in a reduced scale to connect the small patterns.

5. The exposure apparatus according to claim 1, wherein the substrate on which the small patterns are to be projected in a reduced scale has a size of 10 to 20 mm in diameter.
